(19) United States
(12) Patent Application Publication
(10) Pub. No.: US 2014/0048111 A1
(43) Pub. Date: Feb. 20, 2014

(54) METHOD AND SYSTEM FOR PRODUCING AN ELECTRIC CURRENT FROM A TEMPERATURE DIFFERENTIAL

(71) Applicants: THOMAS G. HINSPERGER, Plattsville (CA); Michael A. Walter, Kitchener (CA)

(72) Inventors: THOMAS G. HINSPERGER, Plattsville (CA); Michael A. Walter, Kitchener (CA)

(21) Appl. No.: 13/588,846

(22) Filed: Aug. 17, 2012

(51) Int. Cl. H01L 35/30; H01L 35/34; H01L 35/32

(52) U.S. Cl. 136/201; 136/212; 136/205

(57) ABSTRACT

This invention relates to a method and system for producing electrical current based on a temperature differential. The system comprises of at least one unit having a plurality of chips sandwiched between a higher temperature layer on one side and a lower temperature layer on an opposite side. Chips are preferably thermoelectric solid state chips that produce an electric current when there is a temperature differential created across the chips. There are a plurality of chips in each unit and the chips within each unit are electrically connected to one another in series. Preferably, there are a plurality of units.

### BACKGROUND OF THE INVENTION

1. Field of the Invention

This invention relates to a method and system for producing an electric current by creating a temperature differential. The system has at least one unit containing several chips that produce an electric current when subjected to a temperature differential. The electric current produced can be used to charge a battery or to operate various electrical devices.

2. Brief Description of the Prior Art

It is known that, when two metals or alloys are formed in a closed loop and joined at two junctions and there is a temperature differential between the junctions, an electric current is created in the chip. It is also known to have solid state semiconductor chips (or modules) that produce an electric current when a temperature differential is created across the chips. It is known to have solid state modules having two forms of (n-type and p-type of conductivity) bismuth telluride crystals as a thermoelectric material. Bismuth telluride crystals are a semiconductor.

A voltage differential is created simultaneously with the electric current. One of the difficulties with previous devices is that they produce only a small amount of current and therefore have limited uses or the devices are too expensive compared to the amount of electricity produced or too inefficient, or require high temperature operation (for example, 250 degrees Celsius or higher) or have a limited lifespan and are unmarketable. Both the Seebeck effect (producing an electronic current by creating a temperature gradient across thermoelectric materials) and the Peltier effect (producing a temperature gradient in thermoelectric materials by running an electric current through the materials), are known.

### SUMMARY OF THE INVENTION

It is an object of the present invention to provide a method and system for producing an electric current in a plurality of chips formed into a unit by creating a temperature differential across the chips where the unit has a large output current. The system has at least one unit and each unit contains a plurality of chips formed into at least one layer. The chips can contain any thermoelectric material that will produce an electric current when subjected to a temperature differential.

Without limiting the generality of the forgoing, the thermoelectric material can be two metals or alloys formed into a closed loop and joined at two junctions or, it can be semiconductor materials or metallic crystalline structures or semiconductors and metals in combination.

A system for producing an electric current based on temperature differential comprises at least one unit having at least one layer of a plurality of chips sandwiched between a higher temperature layer on one side and a lower temperature layer on an opposite side. Each chip of the plurality of chips is comprised of a thermoelectric material that produces an electric current when subjected to a temperature differential. At least one of the temperature layers is connected to at least one source to create a temperature differential across the chips. The chips are electrically connected to one another within the unit to produce a current output from the at least one unit that is equal to the current output of an average current output of each chip of the plurality of chips.

A method of producing an electric current based on temperature differential uses a system having at least one unit comprising a plurality of at least one layer of chips sandwiched between a higher temperature layer on one side and a lower temperature layer on an opposite side. Each chip of the plurality of chips is comprised of a thermoelectric material that produces an electric current when subjected to a temperature differential. The method comprises electrically connecting the chips in each unit to one another and connecting at least one of the temperature layers to at least one source to create a temperature differential across the chips, thereby producing a current output from the at least one unit.

### BRIEF DESCRIPTION OF THE DIAGRAMS

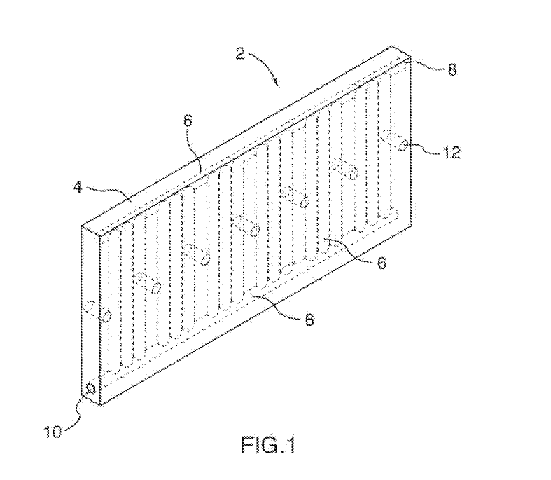

FIG. 1 is a perspective view of a higher temperature layer;

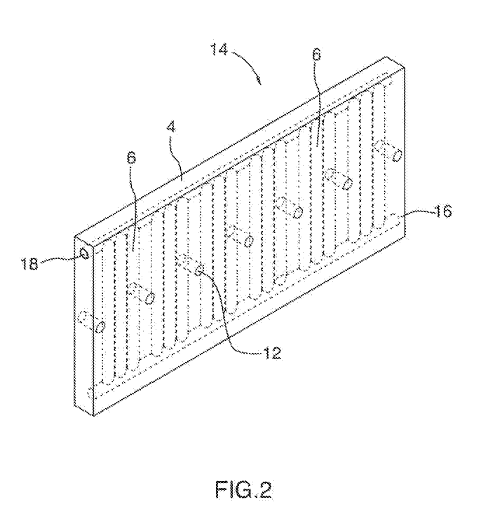

FIG. 2 is a perspective view of a lower temperature layer;

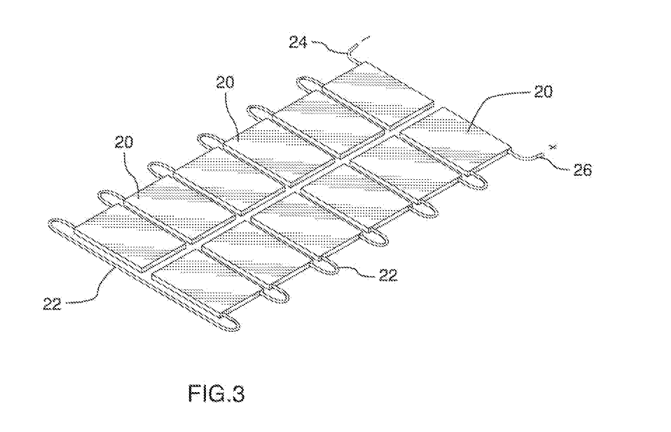

FIG. 3 is a schematic perspective view of a plurality of chips arranged in two row with six chips in each row;

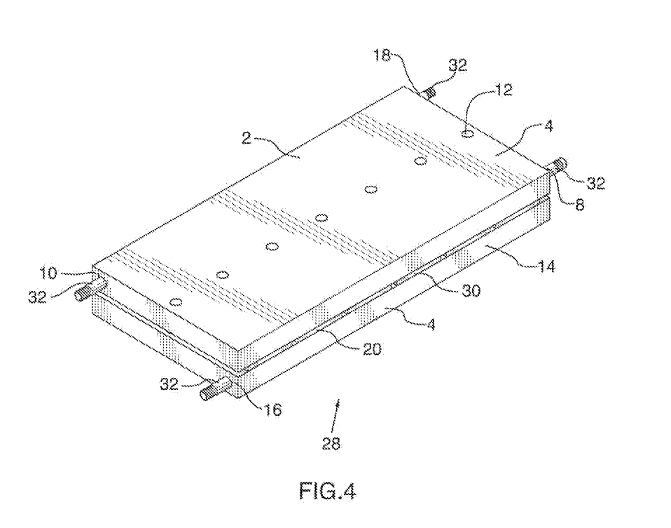

FIG. 4 is a perspective view of one embodiment of the invention with a plurality of chips sandwiched between a higher temperature on one side and a lower temperature layer on an opposite side;

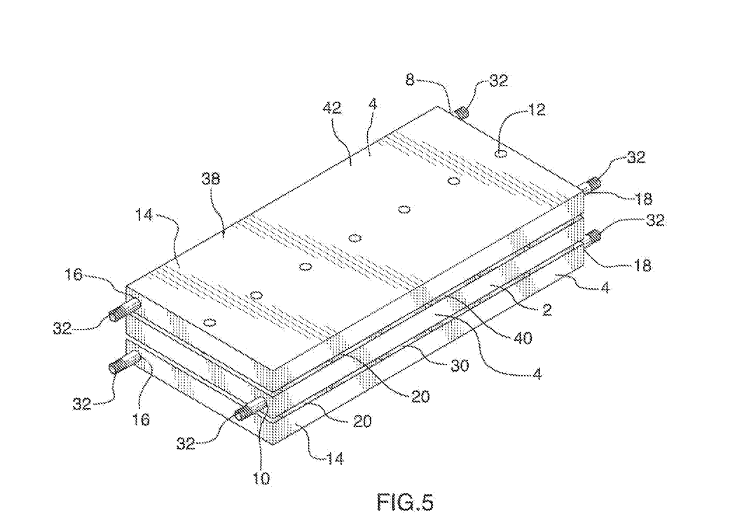

FIG. 5 is a perspective view of a further embodiment of the invention with two rows of chips separated by a higher temperature layer and sandwiched between two lower temperature layers;

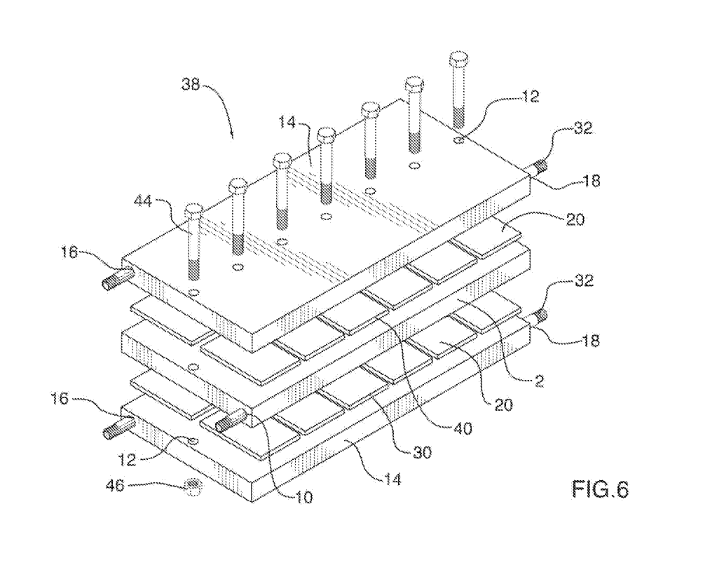

FIG. 6 is an exploded perspective view of the unit shown in FIG. 5;

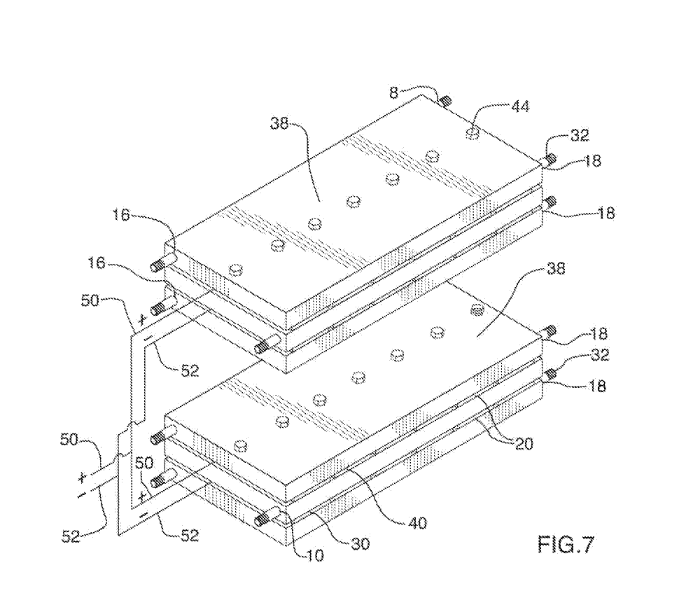

FIG. 7 is a perspective view of two units electrically connected in parallel;

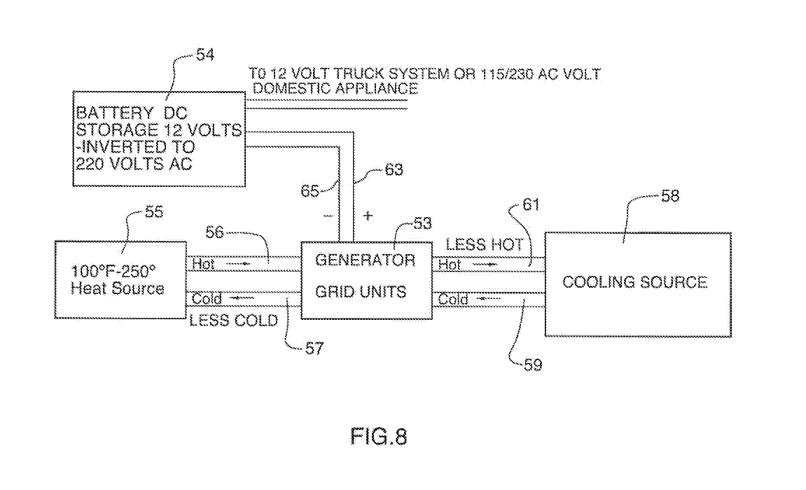

FIG. 8 is a schematic block diagram of a system in accordance with the present invention that is used to charge or supplement a battery;

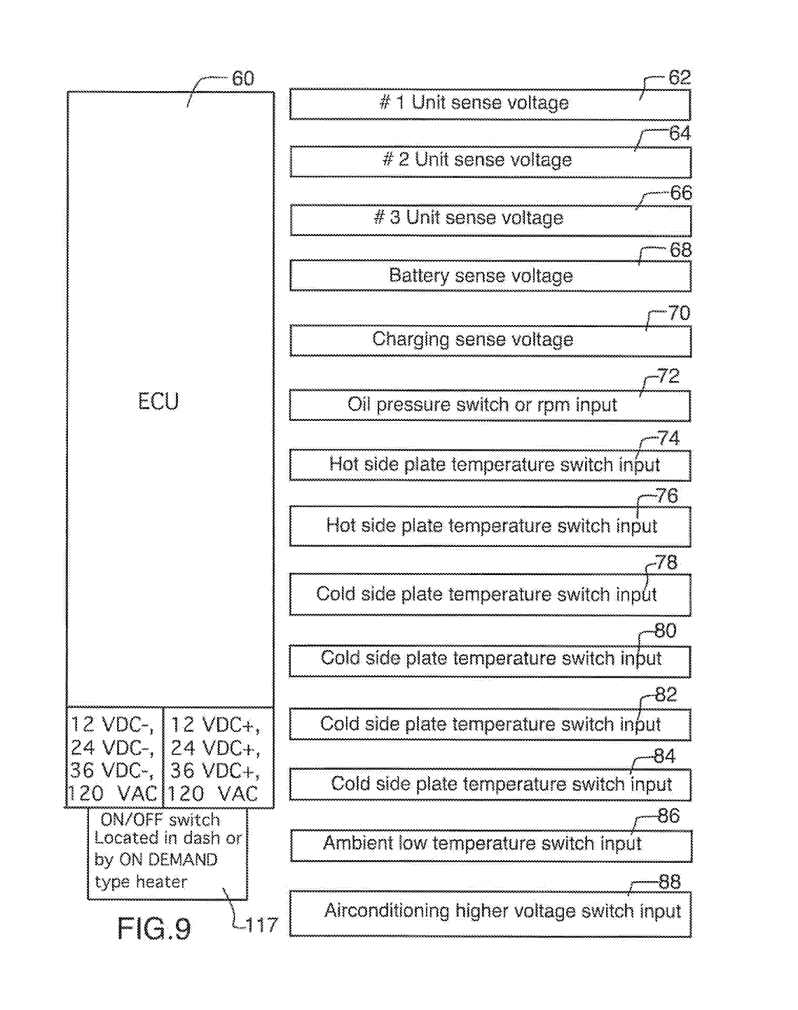

FIG. 9 is a block diagram of electronic control unit (ECU) inputs;

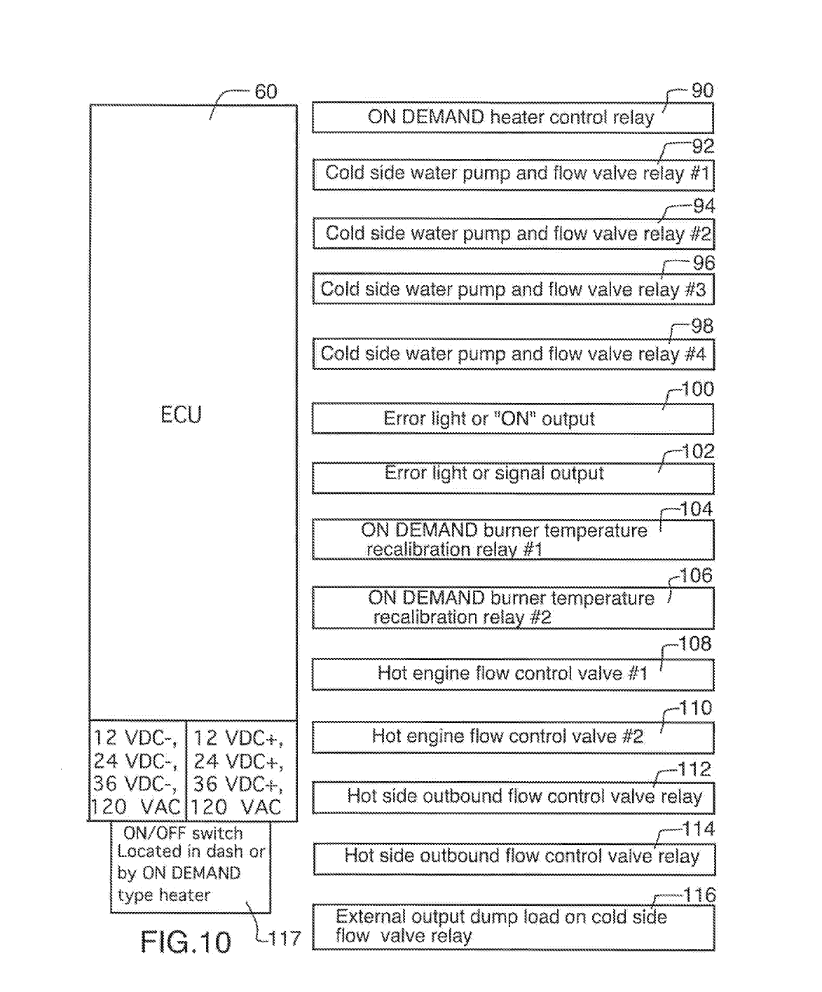

FIG. 10 is a block diagram of ECU outputs;

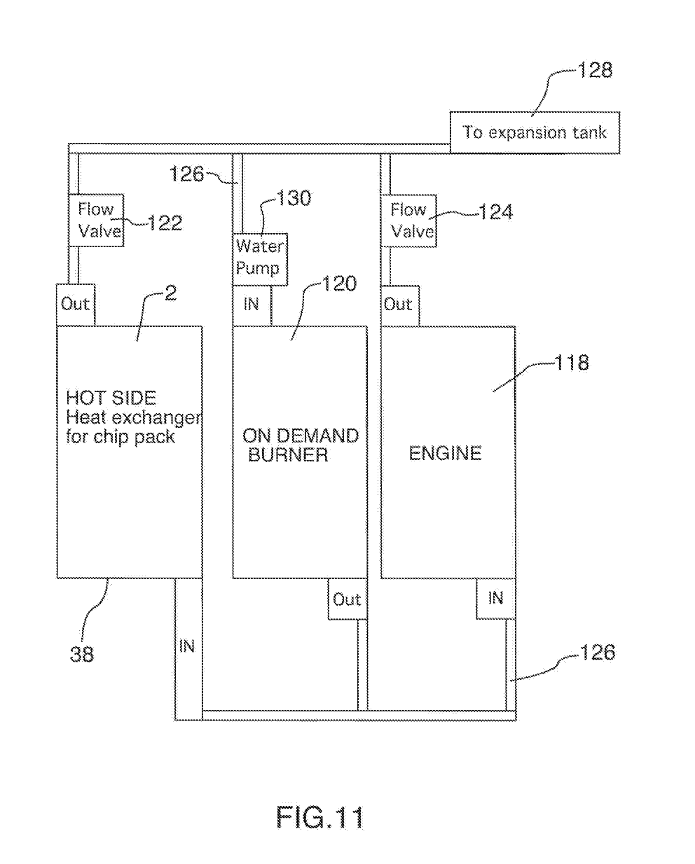

FIG. 11 shows a hot side flow circuit; and

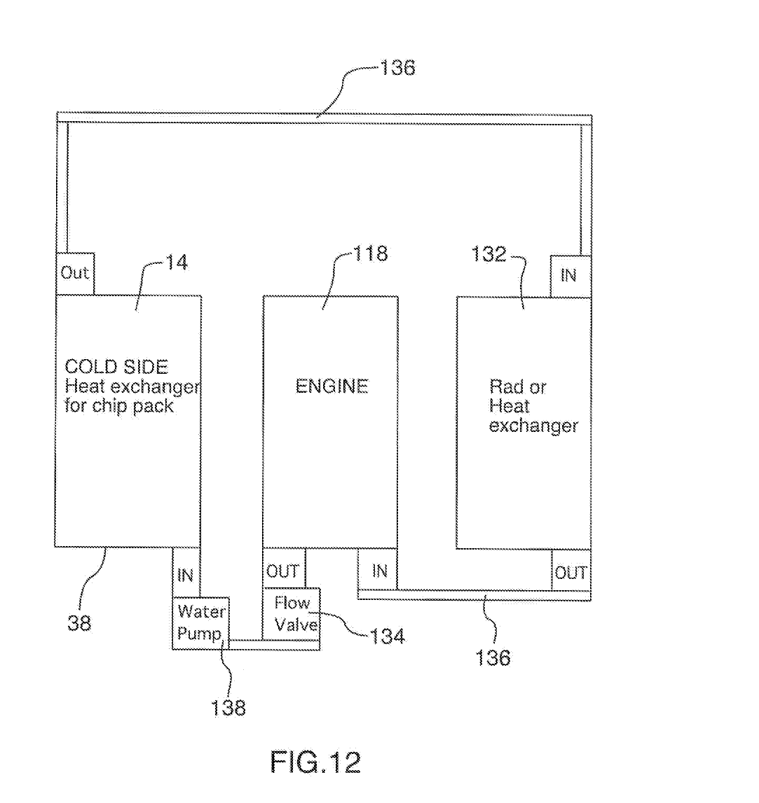

FIG. 12 shows a cold side flow circuit.

### DESCRIPTION OF A PREFERRED EMBODIMENT

FIG. 1 is a perspective view of a higher temperature layer 2 having a rectangularly shaped housing 4 within internal channels 6 exposed for purposes of illustration. Channels 6 are arranged in the form of a grid and the higher temperature layer 2 has a fluid inlet 8 and a fluid outlet 10. There are a plurality of openings 12 that are sized to receive bolts or other fasteners.

FIG. 2 is a perspective view of a lower temperature layer 14, that is identical to the higher temperature layer 2 except that it is oriented upside down relative to the higher temperature layer 2. The lower temperature layer 14 has a fluid inlet 16 and fluid outlet 18. The remaining components of FIG. 2 that are identical to the components of FIG. 1 are described using the same reference numerals.

In FIG. 3, there shown a perspective view of a layer of a plurality of solid state chips 20 that are electrically connected to one another in series by conductors 22. An electrical output 24, 26 can be connected to one or more batteries or to an electrical device or devices (not shown). There are two rows of chips 20 and six chips in each row. The chips 20 are spaced apart from one another to accommodate the opening 12 for the bolts (see FIG. 1) and are preferably Peltier solid state chips. FIG. 4 is a schematic perspective view of a unit 28 having one layer 30 of chips 20 sandwiched between a higher temperature layer 2 and a lower temperature layer 14. The inlets and outlets of the temperature layer 2, 14 have connectors 32 thereon to receive a fluid connection (not shown).

The layers 2, 14 are described as a higher temperature layer and a lower temperature layer respectively because the chips 20 will produce an electric current whenever there is a temperature differential between the two sides of the chips. Therefore, the higher temperature layer can have a hot fluid flowing therethrough and the colder temperature layer can have no fluid flowing therethrough and can simply be the ambient temperature or can have a fluid flowing then through at ambient temperature, or can have a cold temperature fluid flowing therethrough. Similarly, if the lower temperature layer 14 has a cold temperature fluid flowing therethrough, the higher temperature layer can have no fluid flowing therethrough and be at ambient temperature or can have a hot fluid flowing therethrough or can have a fluid flowing therethrough at ambient temperature. When the fluid that is heating or cooling the temperature layer is a gas, the temperature layer preferably has fins thereon to heat or cool the temperature layer and does not have channels.

Preferably, both temperature layers have fluid flowing therethrough even if that fluid is at ambient temperature to maintain the temperature differential.

The chips can be comprised of any thermoelectric material that will produce an electric current when subjected to a temperature differential across the chip. For example, the chips can have two different metals or alloys formed into closed loop, the metals or alloys having two junctions (not shown) or the thermoelectric material can be semiconductor materials or metallic crystalline structures. Preferably, the chips are solid state chips. The chips operate to produce a current in accordance with what is often described as the Seebeck effect. Seebeck solid state chips are much more expensive than Peltier solid state chips as the Seebeck chips can operate at a much higher maximum temperature of approximately 750 degrees Fahrenheit. The Peltier chips operate at a much lower maximum temperature of approximately 250 degrees Fahrenheit. The higher maximum hot side temperature of Seebeck chips is not required for the purposes of the present invention. The cost of Seebeck chips can be five times (or more) than the cost of Peltier chips.

In FIGS. 5 and 6, there is shown a further embodiment of a unit 38 in which there is a second layer 40 of chips 20 and a third temperature layer 42 added to the embodiment shown in FIG. 4 outside of the second layer of chips 20. The inside temperature layer 2 is a higher temperature layer and the two outside temperature layers 14, 42 are lower temperature layers.

The embodiment 38 shown in FIGS. 5 and 6 is preferred, but can be arranged with one lower temperature layer being the inside temperature layer and two higher temperature layers being the two outside temperature layers. When the lower temperature layer is the inside layer and there are two outside higher temperature layers, difficulties can arise in maintaining the temperature of the lower temperature layer as the lower temperature layer receives heat from the two outside layers, thereby decreasing the temperature gradient across the layers of chips.

The openings 12 are not shown in FIGS. 4 and 5, but are shown in FIG. 6. There are bolts 44 and corresponding nuts 46 (only one of which is shown) to fasten the layers together with the two chip layers separated by the inside temperature layer and sandwiched between two outside temperature layers. Numerous other types of fasteners will be suitable, including, without limiting the generality of the forgoing, screws, clamps, cords, tapes and adhesives. The electrical connections and the connections to other units are not shown in FIGS. 5 and 6. The chips within single layer of a unit are always connected in series, but two or more layers of chips 20 within a unit, or two or more units can be connected in parallel or in series or a switch (not shown) can be configured to switch the electrical connection of the units between series and parallel as desired for the most efficient operation.

In FIG. 7, there are two units 38 electrically connected in parallel through conductors 50, 52. As stated previously, the chips within a layer of a unit are always connected in series, but the internal electrical connection of the chips is not shown in FIG. 7.

In FIG. 8, there is shown a block diagram of a system of the present invention in which several units 38 referred to as generator grid units 53 in the drawing have hot and cold fluids flowing through the various temperature layers (not shown) to charge or to provide electric current to a battery or battery storage system 54, which can be used to power other systems. For example, the battery or battery storage system, which is preferably, 12 volts, can be used to power various items of the equipment to be used in relation to a truck, for example, an air conditioning system that is used when the engine of the truck is not operating. The system can be used with motor vehicles other than trucks as well. The DC 12 volt power from the battery can be converted to 115/230 volt AC supply. A heat source 55 is connected by hot inlet line 56 and cold outlet return line 57 to the generator grid units 53 connected to the higher temperature layers (not shown in FIG. 8) of the generator grid units 53. A cooling source 58 is connected through cold inlet line 59 and hot outlet return line 61 to the generator grid units 53. The use of hot and cold to describe the lines 56, 57, 59 and 61 are relative terms and it is to be understood that the hot line 56 from the heat source 55 will be at a much higher temperature than the hot line 61 that is the return line to the cooling source 58. Similarly, the cold line 59 from the cooling source 58 will be much cooler than the cold line 57, which is the return line from the generator grid units 53 to the heat source 55. The temperature differential provided to the generator grid units 53 by the heat source 55 and the cooling source 58 cause a DC current to flow through the electrical lines 63, 65 to the battery or battery storage system 54. Various heat sources can be used and glycol is the preferred heat transfer fluid. For example, the heat sources can be solar tubes. While various fluids can be used, preferably, the fluid is glycol. More preferably, the glycol has a boiling point of 270 to 375 degrees Fahrenheit. Still more preferably, the glycol has a boiling point of substantially 375 degrees Fahrenheit. However, while glycol, without water or other fluids, is the preferred fluid, for both the higher temperature layers and the lower temperature layers, there may be particular circumstances where it is more convenient and/or efficient to use a fluid other than a glycol in one or both of the high temperature layers or lower temperature layers or glycol mixed with one or more other fluids. For example, water can be the fluid used in the lower temperature layer 14, when the source is a well or river. Or glycol and water might be a source of high or low temperature fluid from an engine or radiator. For example, when the engine is running, the fluid from the engine will be hot and the fluid from the radiator will be cooler than the fluid from the engine. When the engine is not running the fluid from the engine or radiator can be a cool source.

In FIGS. 9 and 10, a programmable controller for the system of the present invention is described with FIG. 9 showing an electronic control unit (ECU) 60 having ECU inputs and FIG. 10 showing ECU outputs. The controller is designed for operation of the system for producing electric current based on temperature differential for use of the current in a cab of a truck (not shown) or other motor vehicle, but similar designs can be used for controllers of various other current producing system of the present invention. The system has three units 38 (not shown in FIGS. 9 and 10) with numerous inputs that are monitored by the controller, being a first unit sense voltage 62, a second unit sense voltage 64 and a third unit sense voltage 66. The ECU has further inputs, being a battery sense voltage 68, a charging sense voltage 70 and an oil pressure switch or RPM input 72. In addition, there are two hot side plate switch inputs 74, 76, four cold side plate inputs 78, 80, 82, 84, and an ambient low temperature switch input 86 and an air conditioning higher voltage switch input 88. In FIG. 9, there are a series of ECU outputs. The ECU outputs are an on demand heater control relay 90 and first, second, third and fourth cold side water pump and flow valve relays 92, 94, 96, 98. There is also an error light for “ON” output 100, and error light or signal output 102 and first and second on demand burner temperature recalibration relays 104 and 106. Still further, there are first and second hot engine flow control valves 108, 110, two hot side outbound flow control relays 112, 114 and an external output dump load on cold side flow valve relay 116. The ECU 60 has an on/off switch 117.

In FIGS. 11 and 12 there are shown circuit diagrams for the hot side now and cold side flow of the system respectively. The hot side flow is the flow to the higher temperature layer 2 and the cold side flow is the flow to the lower temperature layer of each unit (not shown in FIGS. 10 and 11).

In FIG. 10, hot fluid, preferably glycol, flows from an engine 118 through an on demand burner 120 to the higher temperature layer 2 of at least one unit 38 having two layers of chips (not shown in FIG. 10). Flow of the fluid can be controlled through flow valves 122, 124 through lines 126. An expansion tank 128 is located to receive any excess fluid. The on demand burner 120 can be configured to be optional as required by the controller based on the temperature differential required in the circumstances. For example, when the engine of the truck is not running and has not run for some time, the fluid from the engine will likely not have a sufficiently high temperature to produce the required current based on the temperature differential between the hot side and the cold side. In that event, the on demand burner will almost always be required, but the diesel fuel required to operate the on demand burner will be far less than the diesel fuel required to run the engine of the truck. Water pump 130 pumps the hot side fluid through the hot side flow circuit.

In FIG. 12, cold side fluid flows from a radiator or other heat exchanger 132, through the cold side of the engine 118, and into the lower temperature layer 14 of the at least one unit. While the fluid is preferably glycol for the cold side flow, the fluid will often more conveniently be a fluid other than glycol or will be glycol and water or water alone. Cold side flow is controlled through flow valve 134 and flow lines 136. Water pump 138 pumps the cold side fluid through the cold side flow circuit.

In operation, when the controller 60 is turned “ON”, the controller is programmed to monitor battery voltage of the truck battery (not shown in FIGS. 9 to 12) and the controller decides whether it should activate the system for producing electricity to charge the battery or certain measures have to be taken to prepare the hot side or the cold side of the units to achieve the required temperature gradient in order for the system to produce the required electric current. If a low ambient temperature is detected, for the hot side, the controller will activate the on demand burner 118 to increase the temperature of the hot side. The flow valve 124 to the engine is closed and the flow valve 122 to the high temperature layer 2 of the at least one unit 38 is open. The hot side fluid circulates through the operating on demand burner and into the higher temperature layer 2 and back to the on demand burner through the water pump 130. Since the ambient temperature is low, it may not be necessary to circulate any fluid through the cold side or lower temperature layer 14 of the unit 38 as the ambient air temperature might be sufficient to achieve the required temperature differential with the hot fluid from the on demand burner on the hot side. However, cold side fluid can be circulated from the radiator or other heat exchanger 132 by opening flow valve 134 and activating water pump 138 to cause low temperature fluid to circulate from the radiator through the non-operating engine or through a bypass around the engine (not shown) to the lower temperature layer 14 of the unit 38 and back to the inlet of the radiator. Even though the pumps 130, 138 are referred to as water pumps, that does not mean that the fluid being pumped is water or even contains water. If the purpose of activating the system was to charge the battery, then the controller will stop the flow of fluid when the charging is complete or, will deactivate the on demand burner when the temperature differential between the hot side and the cold side is sufficient to produce sufficient electric current to continue charging the battery. The on demand burner temperature relay is deactivated in order to deactivate the on demand burner. The controller will activate and deactivate the on demand burner as required until the battery has been fully charged. When the controller is in the on position, it will automatically operate the system to ensure that the battery will be charged as required to maintain a full charge.

In summary, when the ambient temperature is low and DC power is required, the controller will turn on the relay to modify the on demand burner temperature sensor to allow a higher coolant cycling temperature and the on demand burner relay will be activated. Flow valve 124 is closed and flow valve 122 is opened. Similarly, on the cold side, if required, flow valve 134 will be opened and the water pump 138 will be activated as previously described. The controller will deactivate the system when the charging is complete and will activate and deactivate the on demand burner as required to maintain the temperature differential. When the charging is complete, the burner temperature sensor relay is deactivated and the flow valve 122 is closed, and the flow valve 124 is opened so that fluid can flow into the engine. On the cold side, the water pump 138 is deactivated and the flow valve 134 is closed. The system is shut down whenever the engine is running. During initial start-up of the system, the pump or pumps can run using battery power. The battery can then be recharged when the system operates.

When ambient temperature is greater than 40° Fahrenheit and DC power is required, the controller will turn on the relay to modify the on demand burner temperature sensor to allow a higher hot side temperature to be attained. The controller will activate the relay to turn on the on demand burner and the fluid flow valve 124 on the hot side to the engine is closed and the flow valve 122 to the higher temperature layer 2 is open. The water pump relay for the lower temperature layer 14 is activated and the fluid flow control on the cold side is open. The controller stops the on demand burner when sufficiently high temperature is achieved on the hot side and stops the cycle when charging of the battery is complete. The controller shuts down the system by deactivating the on demand burner relay, the burner temperature relay and the lower temperature layer water pump relay. If the cold side is too hot initially, the fluid can be circulated through the engine and radiator for a longer period of time before starting the system.

By way of example, the system of the present invention can be used to charge a twelve volt battery or it can be used to keep the engine warm when the engine is not operating and the weather is cold. The threshold for beginning to charge the battery is 12.6 volts and charging is complete when 13.3 volts is achieved. A unit for procuring electricity from a temperature differential can have twelve chips in a single layer connected in series, preferably arranged in two rows of six chips each. One unit can produce approximately twenty amps of current. The chips are required to produce a voltage of at least twelve volts in order to charge the battery or an average of one volt per chip. In another configuration of a unit, the unit can have twenty-four chips in a single layer, being two outside rows of nine chips each and an inside row of chips, located between the openings for the bolts, of six chips. The twenty-four chips are required to produce a voltage at least equal to or greater than twelve volts or an average of one-half volt per chip. Various numbers of chips and units can be utilized.

When truck drivers are driving a tractor trailer having a sleeper cab, they may want to cook a meal or watch TV or operate other electrical devices (for example, an air conditioner) during their rest period. Since there is a concern that using the electricity supplied from the truck battery when the engine is not operating might cause the truck battery to discharge to such an extent that the truck will not start at the end of the rest period, some truck drivers will operate the electrical equipment with the truck engine running to ensure that the battery will not be discharged, thereby wasting a large amount of fuel. With the present invention, a trucker can operate a small diesel burner or heater to provide heat energy to the higher temperature layer and can use ambient air for the lower temperature layer to create sufficient current to operate the electrical devices and appliances that the driver wishes to use without running the truck engine. The fuel cost of operating the burner will be insignificant compared to the fuel cost of operating the truck engine. The burner is often required to provide heat to the cab during downtime in any event so that the truck motor is not running. Alternatively, if the truck driver uses the truck battery to run the electrical devices and appliances resulting in the truck battery being discharged, a truck driver can use the burner to create a temperature gradient in one or more units of the present invention to charge the truck battery or to assist in starting the truck engine. An inverter can be used to convert the DC current from the unit or units to an AC current when AC current is required.

The diesel heater has an impeller pump thereon that preferably circulates glycol through the motor of the diesel heater to provide the hot side for the one or more units (though one unit should be sufficient). The cold side is glycol pumped through the engine of the tractor of the tractor trailer. Even though it is the cold side, the cold side has sufficient heat to keep the engine warm. Preferably, the cold loop has a larger pump than the hot side as glycol is more viscous and more difficult to pump when it is cold. The two pumps, one for the hot side and one for the cold side, are initially powered from the tractor battery, but, as the unit or units begin to operate, the pumps are powered from part of the current produced by the system for producing electric current from the temperature gradient. For example, there might only be fifteen amps of current produced by a unit initially, but as the temperature gradient between the two sides increases as the system operates, the current output will preferably rise to approximately twenty amps.

The system of the present invention can also be used to heat water in a building or the system can be used in conjunction with a water furnace or the lower temperature layer can be a ground loop in the summertime and can be the higher temperature layer in the winter time. Well water can be used to provide either the higher temperature layer or the lower temperature layer depending on the season of the year. Often, the source of the hot or cold energy that produces the required temperature gradient is waste energy.

While the chips within each single layer of a unit are always electrically connected in series, a plurality of units can be electrically connected to one another in series or in parallel. An electrical connection between the units in parallel produces a higher amperage output of the plurality of units than an electrical connection between the units that is a connection in series. Relays or switches can be used to convert the electrical connections between units from series to parallel or vice-versa. The larger the temperature differential across the chips, the higher the amperage of the current that is produced per chip. If the temperature differential is large enough, the plurality of units can commence operating with the electrical connection between units being a parallel connection. In many situations in which a plurality of units is used, the units are initially electrically connected in series. As the operation continues, the temperature differential increases as the current produced by the chips generates heat on one side of each chip and cold on the other side. When the temperature differential is sufficient, the relay or switch can be used to switch the electrical connection from series to parallel. When there are two or more layers of chips in a single unit, the two or more layers can be connected to one another in series or in parallel and switches or relays can be connected to switch from series to parallel or vice-versa.

If the system of the present invention is being used in a situation where there is an excess of electricity being produced, for example, by a wind turbine, the excess electricity can be used to operate the system to heat or cool by using the excess electricity to run an electric current through the system of the present invention.

The fluid side or temperature layer side of the present invention is always connected in parallel between adjacent units, not in series.

When a unit is switched from series to parallel operation, there will be an increase in the overall amperage output per unit. Ideally, one unit will produce, in one hour, 0.5 kilowatt hours of power.

Depending on the temperature of ambient air and the season of the year, the lower temperature layer in the summer time might be used as the higher temperature layer in the winter time. The temperature layers are preferably made out of aluminum, but can also be made out of copper, and the flow path of the fluid through the temperature layers can be varied from that shown in the drawings. Copper has higher thermal conductivity than aluminum, but is more expensive and is much heavier. The temperature layers can have various internal configurations and can be essentially hollow inside or a grid arrangement can be utilized where the grid is shaped to correspond to the area of the chips that are located adjacent to the temperature layers, or fins can be used externally in lieu of channels.

Glycol is preferably always used on the hot side of the unit unless the fluid on the hot side is air or other gas. Glycol is preferably ethylene glycol or propylene glycol or a blend of both. If there is any possibility of the glycol leaking into potable water or food, propylene glycol is used as ethylene glycol is poisonous if ingested. The fluid in the cold side can vary. Glycol can be used, but sometimes it will be more convenient and efficient to use water, air or other fluids. The chips of the present invention preferably have a maximum operating temperature of 230 degrees Fahrenheit. More preferably, the chips of the present invention have a maximum operating temperature of 250 degrees Fahrenheit and still more preferably, the chips of the present invention have a maximum operating temperature of 270 degrees Fahrenheit. The preferred chips of the present invention are comprised of a crystal with a metal plate on each side. Preferably, the crystal is bismuth telluride or alloys thereof. Twenty-five amp chips or twelve amp chips are preferably used for current production. A lower temperature coefficient Peltier junction chip is preferred, the chip being operated to produce electricity by creating a temperature differential therein. A lower temperature is defined as a temperature up to 270 degrees Fahrenheit. The flow of fluid through the temperature layers is controlled by one or more flow regulators or pumps. The chips preferably have low thermal conductivity (i.e. approximately one to two W/mK (watts per metre Kelvin)).

Flexible washers made from rubber, neoprene or other similar material, are used on the bolts that hold the chip layers and temperature layers together to form a unit. The flexible washers can be used at either end or both ends of the bolts, but are preferably used at one of the two ends only. A metal washer can be used at an opposite end. The use of the flexible washers allows for expansion and contraction of the bolts with variation in temperature. The flexible washers prevent the one or more chip layers from being crushed or otherwise damaged when the bolts contract. When the bolts expand, the flexible washers keep the temperature layers and one or more chip layers together despite the expansion. The flexible washers also allow for visual inspection of the unit to determine that all of the bolts are tightened to approximately the same degree based on the flexible washers for each bolt being compressed by approximately the same amount. For example, three flexible washers can be used on each bolt.

Solid state chips, thermocouples and modules can be purchased from Custom Thermo Electric of Ohio. Hi-Z Technology, Inc also sells solid state chips, but these chips are designed to withstand high temperatures and are recommended to produce an electric current when subjected to a temperature gradient. Preferably, the chips used in the present invention are the low temperature inefficient low conductivity chips that are recommended by the manufacture or supplier as Peltier chips to produce a temperature gradient when a current is passed through the chips (not the Hi-Z Technology solid state chips that are designed to withstand high temperatures).

We claim:

1. A system for producing electric current based on a temperature differential, the system comprising at least one unit having at least one layer of a plurality of lower temperature chips sandwiched between a higher temperature layer on one side and a lower temperature layer on an opposite side, each chip of the plurality of chips being comprised of a thermoelectric material that produces an electric current when subjected to a temperature differential, at least one of the temperature layers being connected to at least one source to create a temperature differential across the chips, the chips being electrically connected to one another within the unit to produce a current output from the at least one unit.

2. A system as claimed in claim 1 wherein at least one of the temperature layers has channels located therein to receive a fluid that flows through the at least one of the temperature layers to heat or cool the layer.

3. A system as claimed in claim 1 wherein both the higher temperature layer and the lower temperature layer contain channels to receive fluids, the higher temperature layer having a different source of fluid from the lower temperature layer.

4. A system as claimed in claim 1 wherein individual chips of each layer of chips of each unit are spaced apart from one another and the plurality of chips within each layer is connected in series.

5. A system as claimed in claim 2 wherein there are a plurality of units, the current outputs of which are electrically connected to produce a current output for the device.

6. A system as claimed in claim 1 wherein the temperature layers are fastened together with the plurality of chips in between.

7. A system as claimed in claim 3 wherein the temperature layers of each unit have connectors at opposite ends of each layer for connection to a fluid source.

8. A system as claimed in claim 1 wherein the chips are each capable of withstanding temperatures of up to 270 degrees Fahrenheit.

9. A system as claimed in claim 7 wherein the channels of each temperature layer are in the form of grids.

10. A system as claimed in claim 4 wherein the fluid flowing through the channels is glycol.

11. A system as claimed in claim 1 wherein the chips are Peltier chips.

12. A system as claimed in claim 4 wherein there are a plurality of units and the higher temperature layer and the lower temperature layer are connected in parallel to other higher temperature layers and other lower temperature layers respectively of the plurality of temperature layers.

13. A system as claimed in claim 12 wherein the units are electrically connected in one of series or parallel.

14. A system as claimed in claim 13 wherein a switch is a configured to allow the electrical connection between units to be switched to series from parallel or vice-versa.

15. A system as claimed in claim 3 wherein the fluid flowing through the higher temperature layer is glycol.

16. A system as claimed in claim 3 wherein at least some of the units have two layers of chips and three temperature layers, the two layers of chips being separated by a temperature layer and each layer of chips having a temperature layer outside of the layer of chips, there being an inside temperature layer and two outside temperature layers, the inside temperature layer having a temperature different from the outside temperature layers.

17. A system as claimed in claim 16 wherein the temperature layer separating the two layers of chips is a higher temperature layer and the outside temperature layers are lower temperature layers.

18. A system as claim in claim 4 wherein the flow of fluid through the temperature layers is controlled by one or more flow regulators.

19. A system as claimed in claim 4 wherein the temperature layers are made from one of aluminum and copper.

20. A system as claimed in claim 1 wherein each unit of the at least one unit has two rows of chips with six chips in each row, the chips being spaced apart from one another.

21. A system as claimed in claim 1 wherein there is a plurality of units of the at least one unit, the units are electrically connected in series or in parallel.

22. A system as claimed in claim 4 wherein a grid in the temperature layers is shaped to correspond to the size and location of the chips.

23. A system as claimed in claim 4 wherein there are one or more pumps to pump the fluid through the temperature layers and to control the flow of fluid.

24. A system as claimed in claim 15 wherein the glycol has a boiling point of substantially 375 degrees Fahrenheit.

25. A system as claimed in claim 1 wherein the chips are each capable of withstanding a temperature of up to 250 degrees Fahrenheit.

26. A system as claimed in claim 1 wherein the chips are each capable of withstanding a temperature of up to 230 degrees Fahrenheit.

27. A system as claimed in claim 1 wherein the thermoelectric material is one of a semiconductor, a metallic crystal, a bismuth telluride crystal, two different metals or alloys formed into a closed loop, the metals or alloys having two junctions.

28. A system as claimed in claim 1 wherein the chips have low thermal conductivity.

29. A system as claimed in claim 3 wherein there is a programmable controller to automatically control the temperature differential and the flow rate of fluid for each side of the chips to produce the required current.

30. A system as claimed in claim 29 wherein there is a heater to increase the temperature of the fluid flowing through the higher temperature layer of the at least one unit, the controller being programmed to operate the heater to achieve the required temperature differential.

31. A method of producing an electric current based on temperature differential, the device having at least one unit comprising of plurality at least one layer of chips sandwiched between a higher temperature layer on one side and a lower temperature layer on an opposite side, each chip of the plurality of chips being comprised of a thermoelectric material that produces an electric current when subjected to a temperature differential, the method comprising electrically connecting the chips in the at least one layer in each unit to one another and connecting at least one of the temperature layers to at least one source to create a temperature differential across the chips, thereby producing a current output from the at least one unit.

32. A method as claimed in claim 31 including the step of using at least twelve chips in the at least one layer of the plurality of chips of the at least one unit, achieving the temperature differential by applying a higher temperature fluid through the higher temperature layer and a lower temperature fluid through the lower temperature layer.

33. A method as claimed in claim 31 including the step of electrically connecting each layer of chips within each unit in series.

34. A method as claimed in claim 31 including the steps of using at least two units of the plurality of units and fluidly connecting the at least two to one another in parallel and electrically connecting the at least two units to one another in one of series or parallel.

35. A method as claimed in claim 31 including the steps of adding a second layer of chips to each unit along with an outside temperature layer adjacent to the second layer of chips, sandwiching the second layer of chips between the outside temperature layer and one of the two previous temperature layers and choosing the temperature of the outside temperature layer to create a temperature gradient across the second layer of chips.

36. A method as claimed in claim 32 wherein there is a programmable controller to operate the at least one unit, the method including the steps of programming the controller to control the flow rate of the higher temperature fluid and the lower temperature fluid and to control the temperature of the higher temperature fluid.

37. A method as claimed in claim 36 including the steps of having the controller operate a heater to control the temperature of the higher temperature fluid to maintain the required temperature differential.

38. A method as claimed in claim 36 including the step of programming the controller to control the temperature of the lower temperature fluid.
